(19) United States
(12) Patent Application Publication
(10) Pub. No.: US 2018/0163298 A1
(43) Pub. Date: Jun. 14, 2018

(54) DEVICE FOR PRODUCING CONTINUOUS-GROWTH TYPE LARGE-AREA TRANSPARENT AND CONDUCTIVE GRAPHENE FILM

(71) Applicant: National Chung-Shan Institute of Science and Technology, Taoyuan City (TW)

(72) Inventors: WU-CHING HUNG, Taoyuan City (TW); CHIEN-LIANG CHANG, Taoyuan City (TW)

(21) Appl. No.: 15/378,872

(22) Filed: Dec. 14, 2016

(51) Int. Cl. C23C 16/26; C23C 16/54; C23C 16/50; C23C 16/46

(52) U.S. Cl. CPC C23C 16/26; C23C 16/54; C23C 16/50; B82Y 40/00; C01B 31/0453; C01B 2204/22; C23C 16/46

(57) ABSTRACT

A device for producing a continuous-growth type large-area transparent and conductive graphene film, comprising: a heating unit, used to heat a substrate; a feed-in unit, used to transform a rolling type substrate into a plane type substrate, while the substrate is transported from the feed-in unit to the heating unit; a receiving unit, used to transform the plane type substrate into the rolling type substrate; an atmosphere unit, used to control input gas flow ratio; and a plasma unit, used to turn the input gas into plasma, while a carbon source gas flows from the atmosphere unit, to the heating unit, through the plasma unit. As such, when the plane type substrate is transported through the heating unit, the transparent and conductive graphene film can be formed on the plane type substrate.

### BACKGROUND OF THE INVENTION

### Field of the Invention

The present invention relates to a device for producing graphene film, and in particular to a device for producing continuous-growth type large-area transparent and conductive graphene film.

### The Prior Arts

The research of graphene has become very popular and is a focus of attention in recent years, since Geim et al. conducted the experiment to obtain a single layer graphene from a multi-layer stack structure of graphite in 2004. And it is found that, the single layer graphene has excellent physical properties concerning electron conductivity (200,000 cm²V⁻¹ s⁻¹), mechanical strength (125Gpa), tensile modulus (1.1Gpa), specific surface area (2,630 m² g⁻¹), and thermal conductivity (5,000 Wm⁻¹K⁻¹).

The existing technologies used for producing graphene include the following approaches: Mechanical Exfoliation, Epitaxial Growth, Chemical Vapor Deposition (CVD), Chemical Exfoliation, Reduced Graphene Oxide (RGO), and Electrochemical Exfoliated Graphene (EC graphene), etc. However, for the approaches mentioned above capable of mass production, they all have their deficiencies. The Mechanical Exfoliation approach is not able to control precisely the size and position of the object-in-process, therefore, it can not control precisely the quality of the graphene produced. The Reduced Graphene Oxide (RGO) approach is capable of mass production, yet its production process includes acid oxidation, thus leading to destruction of graphene structure, and loss of its original physical properties. In contrast, the Chemical Vapor Deposition (CVD) approach has the advantages that, it is capable of growing large-area graphene on the surface of a substrate made of copper or nickel, while achieving high crystallinity of graphene. Further, graphene can be trans-printed on a variety of substrates, to have wide applications in the Industries.

In producing optoelectronic elements, the transparent conduction film is essential. Presently, the transparent conduction film utilized are mostly Indium-Tin-Oxide (ITO) films. Due to the forthcoming depletion of Indium and the requirement of the flexible electronics, quite a lot of conduction materials have been developed for this purpose, such as carbon nanotube, graphene nano wires, and metal nano wires. In this respect, the research of graphene has become very popular in recent years, due to its unique structure and property, and it has high degree of freedom in selecting the substrates utilized. As such, it is capable of raising the applicability of the transparent conduction film, to make it to have wide application in the Industries. In this respect, though Chemical Vapor Deposition (CVD) is capable of producing large-area high quality graphene, yet it has to go through process of high temperature up to 1000° C., thus limiting development of equipment used for mass production. Therefore, presently, there is a need for a manufacturing equipment, that is capable of producing continuous-growth type large-area transparent and conductive graphene film, while reducing its cost significantly, to raise its competitive edge in the market.

Therefore, presently, the design and performance of the graphene film is not quite satisfactory, and it leaves much room for improvement.

### SUMMARY OF THE INVENTION

In view of the problems and drawbacks of the prior art, the present invention provides a device for producing a continuous-growth type large-area transparent and conductive graphene film, including a heating unit, a feed-in unit, a receiving unit, an atmosphere unit, and a plasma unit, to produce continuously large-area transparent and conductive graphene films of high quality.

To achieve the objective mentioned above, the present invention provides a device for producing a continuous-growth type large-area transparent and conductive graphene film, including: a heating unit, used to heat a substrate; a feed-in unit, used to transform a rolling type substrate into a plane type substrate, while the substrate is transported from the feed-in unit to the heating unit; a receiving unit, used to transform the plane type substrate into the rolling type substrate, while the substrate is transported from the heating unit to the receiving unit; an atmosphere unit, used to control input gas flow ratio, the input gas includes a carbon source gas, an activation gas, and a protection gas; and a plasma unit, used to turn the carbon source gas, the activation gas, and the protection gas into plasma, while the input gas is transported from the atmosphere unit to the heating unit, through the plasma unit. As such, when the plane type substrate is transported through the heating unit, the transparent and conductive graphene film can be formed on the plane type substrate.

The heating unit includes: a heating chamber, a heating substrate, a graphite temperature equalizing plate, a graphite blanket temperature retaining device, a heating chamber vacuum pump, and a cooling wheel system. Outside the heating chamber is wrapped around with a water layer, to protect the heating chamber from being damaged by overly high temperature. The heating chamber vacuum pump is used to vacuum the heating chamber, to purify the atmosphere inside the heating chamber. The cooling wheel is used to connect the substrate feeding-in and the substrate receiving, to cool the temperature of the substrate, to prevent and protect the feed-in unit and the receiving unit from being damaged by overly high temperature.

The feed-in unit includes a feed-in chamber, a roll-to-roll feed-in wheel, a roll-to-roll feed-in tension control wheel, a roll-to-roll feed-in power transmission system, a feed-in guidance and detection system, a roll-to-roll feed-in edge finding device, a feed-in chamber vacuum pump, and a roll-to-roll feed-in vacuum shielding valve. The feed-in guidance and detection system acts in cooperation with the roll-to-roll feed-in tension control wheel, and the roll-to-roll feed-in power transmission system, to control the substrate feed-in tension and correct the substrate position. The roll-to-roll feed-in edge finding device is used to adjust and align automatically one side of the fed in object. The roll-to-roll feed-in vacuum shielding valve is used to shield the atmosphere inside the heating chamber from being contacted by the outside air atmosphere when replacing a substrate reel, while the device of the present invention is in operation. Therefore, the substrate reel can be replaced without having to stop the production line.

The receiving unit includes a receiving chamber, a roll-to-roll receiving wheel, a roll-to-roll receiving tension control wheel, a roll-to-roll receiving power transmission system, a receiving guidance and detection system, a roll-to-roll receiving edge finding device, a receiving chamber vacuum pump, and a roll-to-roll receiving vacuum shielding valve. The receiving guidance and detection system acts in cooperation with the roll-to-roll receiving tension control wheel, and the roll-to-roll receiving power transmission system, to control the substrate receiving tension and correct the substrate position. The receiving guidance and detection system and the roll-to-roll receiving edge finding device are used to adjust and align automatically one side of the feed-in object. The roll-to-roll receiving vacuum shielding valve is used to shield the atmosphere inside the heating chamber from being contacted by the outside air atmosphere when replacing a substrate reel, while the device of the present invention is in operation. Therefore, the substrate reel can be replaced without having to stop the production line.

The atmosphere unit includes a process gas system, that utilizes a gas flow controller to control the gas flow ratio of the gases input to the heating chamber, while the input gas utilizes a carbon-containing compound gas of methane (CH₄) or acetylene (C₂H₂) as a carbon source gas, a hydrogen gas (H₂) or a hydrogen-containing compound gas as an activation gas, and an argon or an inert gas as a protection gas.

The plasma unit includes a plasma power supplier, used to supply power required for converting gas into plasma and for plasma control.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from the detail descriptions.

### BRIEF DESCRIPTION OF THE DRAWINGS

The related drawings in connection with the detailed descriptions of the present invention to be made later are described briefly as follows, in which:

FIG. 1 is schematic diagram of a device for producing a continuous-growth type large-area transparent and conductive graphene film according to an embodiment of the present invention.

### DETAILED DESCRIPTION OF THE PREFERRED EMBODIMENT

The purpose, construction, features, functions and advantages of the present invention can be appreciated and understood more thoroughly through the following detailed descriptions with reference to the attached drawings.

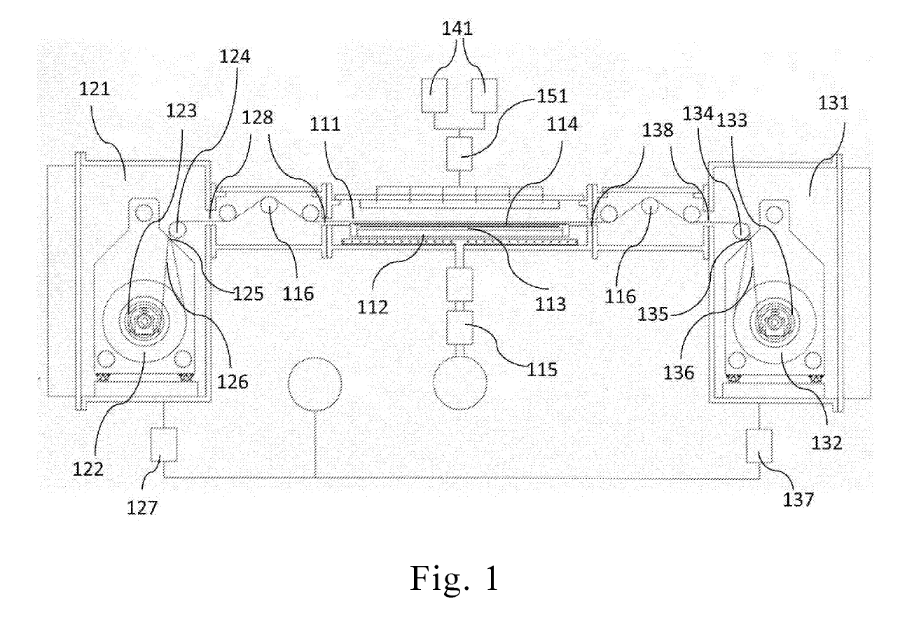

Refer to FIG. 1 for a device for producing a continuous-growth type large-area transparent and conductive graphene film according to an embodiment of the present invention.

As shown in FIG. 1, the present invention provides a device for producing a continuous-growth type large-area transparent and conductive graphene film, including: a heating unit, a feed-in unit, a receiving unit, an atmosphere unit, and a plasma unit.

The heating unit includes the following items used for heating a substrate: a heating chamber 11, a heating substrate 112, a graphite temperature equalizing plate 113, a graphite blanket temperature retaining device 114, a heating chamber vacuum pump 115, and a cooling wheel system 116. A water layer is wrapped around the heating chamber 111, to protect it from being damaged by overly high temperature inside. The heating chamber vacuum pump 115 is used to pump the heating chamber 111 into vacuum, to purify the atmosphere inside the heating chamber 111. The cooling wheel system 116 is used to prevent the overly high temperature in the heating chamber 111 from being transferred to other units through a substrate, and leading to failure of other units.

The feed-in unit includes: a feed-in chamber 121, a roll-to-roll feed-in wheel 122, a roll-to-roll feed-in tension control wheel 124, a roll-to-roll feed-in power transmission system 123, a feed-in guidance and detection system 125, a roll-to-roll feed-in edge finding device 126, a feed-in chamber vacuum pump 127, and a roll-to-roll feed-in vacuum shielding valve 128. The feed-in unit is used to transform the rolling type substrate into the plane type substrate, while the substrate is transported from the feed-in unit to the heating unit. The feed-in guidance and detection system 125 acts in cooperation with the roll-to-roll feed-in tension control wheel 124, and the roll-to-roll feed-in power transmission system 123, to control the substrate feed-in tension and correct the substrate position. The roll-to-roll feed-in edge finding device 126 is used to adjust and align automatically one side of the fed in object. The roll-to-roll feed-in vacuum shielding valve 128 is used to shield the atmosphere inside the heating chamber 111 from being contacted by the outside air atmosphere when replacing a substrate reel, while the device of the present invention is in operation. Therefore, the substrate reel can be replaced without having to stop the production line. The rolling type substrate used for feed-in is made of metal or alloy, or it is formed by depositing metal or alloy onto the metal foil of the rolling type substrate.

The receiving unit includes a receiving chamber 131, a roll-to-roll receiving wheel 132, a roll-to-roll receiving tension control wheel 134, a roll-to-roll receiving power transmission system 133, a receiving guidance and detection system 135, a roll-to-roll receiving edge finding device 136, a receiving chamber vacuum pump 137, and a roll-to-roll receiving vacuum shielding valve 138. The receiving unit is used to transform the plane type substrate into the rolling type substrate, while the substrate is transported from the heating unit to the receiving unit. The receiving guidance and detection system 135 acts in cooperation with the roll-to-roll receiving tension control wheel 134, and the roll-to-roll receiving power transmission system 133, to control the substrate receiving tension and correct the substrate position. The receiving guidance and detection system 135 and the roll-to-roll receiving edge finding device 136 are used to adjust and align automatically one side of the fed in object. The roll-to-roll receiving vacuum shielding valve 138 is used to shield the atmosphere inside the heating chamber 111 from being contacted by the outside air atmosphere when replacing a substrate reel, while the device of the present invention is in operation. Therefore, the substrate reel can be replaced without having to stop the production line.

The atmosphere unit includes a process gas system 141, that utilizes a gas flow controller to control the gas flow ratio of the gases input to the heating chamber 111, while the input gas utilizes a carbon-containing compound gas of methane (CH₄) or acetylene (C₂H₂) as a carbon source gas, a hydrogen gas (H₂) or a hydrogen-containing compound gas as an activation gas, and an argon or inert gas as a protection gas.

The plasma unit includes a plasma power supplier 151, used to supply power required for converting gas into plasma, while the input gas is transported from the atmosphere unit to the heating unit through the plasma unit.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A device for producing a continuous-growth type large-area transparent and conductive graphene film, comprising:
a heating unit, used to heat a substrate;
a feed-in unit, used to transform a rolling type substrate into a plane type substrate, while the substrate is transported from the feed-in unit to the heating unit;
a receiving unit, used to transform the plane type substrate into the rolling type substrate;
an atmosphere unit, used to control input gas flow ratio; and
a plasma unit, used to turn the input gas into plasma, while a carbon source gas flows from the atmosphere unit to the heating unit, through the plasma unit.

2. The device for producing a continuous-growth type large-area transparent and conductive graphene film as claimed in claim 1, wherein the heating unit includes a heating chamber, a heating substrate, a graphite temperature equalizing plate, a graphite blanket temperature retaining device, a heating chamber vacuum pump, and a cooling wheel system.

3. The device for producing a continuous-growth type large-area transparent and conductive graphene film as claimed in claim 1, wherein the heating unit is a high temperature thermal processing vacuum furnace.

4. The device for producing a continuous-growth type large-area transparent and conductive graphene film as claimed in claim 1, wherein for the heating unit, outside the heating chamber is wrapped around with a water layer, and is disposed the cooling wheel system, to protect the device from being damaged by overly high temperature.

5. The device for producing a continuous-growth type large-area transparent and conductive graphene film as claimed in claim 1, wherein the feed-in unit includes a feed-in chamber, a roll-to-roll feed-in wheel, a roll-to-roll feed-in tension control wheel, a roll-to-roll feed-in power transmission system, a feed-in guidance and detection system, a roll-to-roll feed-in edge finding device, a feed-in chamber vacuum pump, and a roll-to-roll feed-in vacuum shielding valve.

6. The device for producing a continuous-growth type large-area transparent and conductive graphene film as claimed in claim 1, wherein the rolling type substrate used for feed-in is made of metal or alloy, or it is formed by depositing the metal or the alloy onto metal foil of the rolling type substrate.

7. The device for producing a continuous-growth type large-area transparent and conductive graphene film as claimed in claim 1, wherein the receiving unit includes a receiving chamber, a roll-to-roll receiving wheel, a roll-to-roll receiving tension control wheel, a roll-to-roll receiving power transmission system, a receiving guidance and detection system, a roll-to-roll receiving edge finding device, a receiving chamber vacuum pump, and a roll-to-roll receiving vacuum shielding valve.

8. The device for producing a continuous-growth type large-area transparent and conductive graphene film as claimed in claim 1, wherein the atmosphere unit includes a process gas system.

9. The device for producing a continuous-growth type large-area transparent and conductive graphene film as claimed in claim 1, wherein the atmosphere unit input gas utilizes carbon containing compound gas of methane (CH₄) or acetylene (C₂H₂) as a carbon source gas, hydrogen gas (H₂) or hydrogen-containing gas as an activation gas, argon or inert gas as a protection gas.

10. The device for producing a continuous-growth type large-area transparent and conductive graphene film as claimed in claim 1, wherein the plasma unit includes a plasma power supplier.
